(19) United States
(12) Patent Application Publication
(10) Pub. No.: US 2008/0218242 A1
(43) Pub. Date: Sep. 11, 2008

(54) OUTPUT SIGNAL SWITCHING DEVICE

(75) Inventor: Kazunori Kato, Izu-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: TOSHIBA TEC KABUSHIKI KAISHA, Tokyo (JP)

(21) Appl. No.: 11/684,273

(22) Filed: Mar. 9, 2007

(51) Int. Cl. H03K 17/00

(52) U.S. Cl. 327/365

(57) ABSTRACT

An output signal switching device includes a switching unit connected to a base board and a detection resistor. The voltage of the detection resistor is set to be constant by a resistor. The expansion board includes the detection resistor. When being connected to the expansion board, the switching unit interrupts a signal inputted to the switching unit from the base board.

### BACKGROUND OF THE INVENTION

1. Field of the Invention

The present invention relates to an output signal switching device including switching means for, when an expansion board is connected to a motherboard of a computer or the like, causing an output signal to be automatically outputted from the expansion board.

2. Description of the Related Art

For example, in the case where a video card is added to a motherboard of a computer, hitherto, a plurality of control signals of an interface are used to detect the expansion board, and a complicated circuit is used to perform switching so that an output signal outputted from an internal video adapter is outputted from the expansion board. Alternatively, the expansion board is detected by hardware, and software is also used to perform the above switching. Thus, it is necessary to develop the circuit and the software, and there has been a problem that the manufacture cost is increased.

In this point, there is proposed a technique in which an IDSEL (device identification signal line) MASK/Unmask Module is provided between an internal video adapter module and a system bus, and when a computer system starts up, an expansion video card is recognized, and when the IDSEL Mask/Unmask Module receives a masking signal from a GPIO, the IDSEL Mask/Unmask Module disables an IDSEL, makes the internal video adapter inoperative, and makes the expansion video card operable (U.S. Pat. No. 6,094,690). However, also in this technique, it is necessary to develop the complicated hardware of the IDSEL Mask/Unmask Module and the software to operate this, and there has been a problem that the manufacture cost becomes high.

Besides, there is proposed a technique in which an IEEE 1394 serial bus is provided in a central controller and an additional equipment, the plug and play function of the IEEE 1394 is used to configure a network, and the central controller controls the additional equipment (JP-A-2000-175275). However, in this technique, the IEEE 1394 interface must be provided in the central controller and the additional equipment, and with respect to the central controller and the additional equipment, it is necessary to develop the software by which the central controller controls the additional equipment, and there has been a problem that the manufacture cost becomes high.

### BRIEF SUMMARY OF THE INVENTION

It is an object of the present invention to provide an output signal switching device including switching means for, when an expansion board is connected, causing an output signal to be outputted from the expansion board.

In an aspect of the present invention, an output signal switching device includes

a switching unit that is connected to a base board, is connectable to an expansion board, interrupts an input signal from the base board when the expansion board is detected, and outputs the input signal from the base board when the expansion board is not detected; and

a detection resistor electrically connected to the switching unit for detecting the expansion board.

### BRIEF DESCRIPTION OF THE DRAWINGS

FIG. 1 is a view showing a schematic structure of a case where an output signal switching device of an embodiment of the invention is applied to a computer.

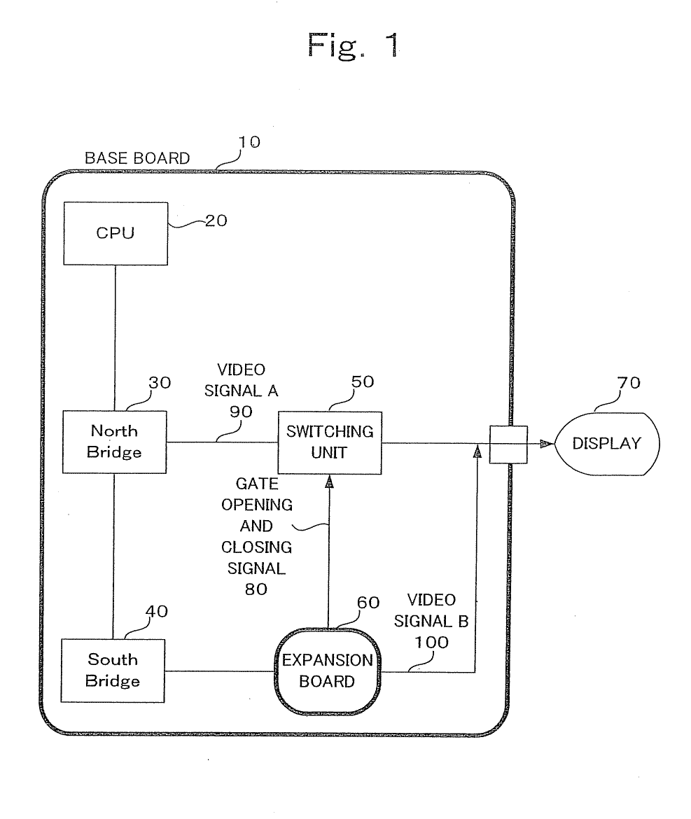

### DETAILED DESCRIPTION OF THE INVENTION

Throughout this description, the embodiments and examples shown should be considered as exemplars, rather than limitations on the apparatus and methods of the present invention.

Hereinafter, an embodiment of an output signal switching device of the invention will be described in detail by use of the drawings.

In this embodiment, a description will be made while a case where a video card is added to a motherboard of a computer is used as an example. An output signal switching device of this embodiment includes a base board 10 as a motherboard and an expansion board 60 as a video card.

The base board 10 includes a CPU 20, an interface to connect the expansion board 60, and a switching unit 50 to switch a signal. As long as the expansion board can be connected, the standard for the interface is arbitrary. For example, the PCI bus, the VME bus and the ISA bus are enumerated. In the base board 10 of the embodiment, the switching unit 50 is connected to a North Bridge 30, and the interface is connected to a South Bridge 40. The North Bridge is a chip connected to the CPU in a chip set of a 2-chip structure, and the South Bridge is a chip connected to the North Bridge.

The switching unit 50 includes an expansion board connection part connected to the expansion board 60, a video signal A input part to input a video signal, a video signal A output part to output a video signal, and a gate IC to switch signals.

The expansion board 60 includes an interface connection part connected to a slot of an interface of the South Bridge 40, a switching unit connection part having a detection resistor including a pull-up resistance or a pull-down resistance and connected to the switching unit 50, and a video signal B output part to output a video signal.

Next, the operation of the switching unit 50 will be described. Before the expansion board 60 is connected, the video signal A outputted from the North Bridge 30 is outputted from the base board through the switching unit 50.

When the expansion board 60 is connected, the interface connection part of the expansion board 60 is inserted in a slot, the switching unit connection part of the expansion board 60 and the expansion board connection part of the switching unit 50 are connected to each other, and power is applied to the base board. The switching unit 50 is structured such that when the gate IC is used to detect a gate opening and closing signal 80 as a voltage set by the detection resistor of the expansion board, a video signal A 90 inputted from the CPU is interrupted. The expansion board 60 receives a signal from the South Bridge 40 and outputs a video signal B 100. Thus, only the video signal B 100 from the expansion board 60 is outputted to a display 70. Here, a resistor of the expansion board used when the motherboard 10 detects the expansion board may also be used as the detection resistor.

When the expansion board 60 is detached from the base board, since the switching unit 50 does not detect the opening and closing signal 80, the video signal A 90 is not interrupted but is outputted.

As described above, the output signal switching device of the embodiment includes only the one resistor and the gate IC for signal switching as the main parts, and the passage and interruption of the signal is performed according to the existence of the connection of the expansion board. Thus, the number of parts required for manufacture is very small, and software to operate the switching unit is unnecessary. Accordingly, the development of the output signal switching device of the embodiment is easy, and it can be provided at low cost. Besides, since the structure is simple, the ratio of failure occurrence is also very small.

Although exemplary embodiments of the present invention have been shown and described, it will be apparent to those having ordinary skill in the art that a number of changes, modifications, or alterations to the invention as described herein may be made, none of which depart from the spirit of the present invention. All such changes, modifications, and alterations should therefore be seen as within the scope of the present invention.

What is claimed is:

1. An output signal switching device comprising:
a switching unit that is connected to a base board, is connectable to an expansion board, interrupts an input signal from the base board when the expansion board is detected, and outputs the input signal from the base board when the expansion board is not detected; and
a detection resistor electrically connected to the switching unit and for detecting the expansion board.

2. The output signal switching device according to claim 1, wherein the detection resistor is provided on the expansion board.

3. The output signal switching device according to claim 1 or 2, wherein a resistance of the detection resistor is a pull-up resistance or a pull-down resistance.

4. The output signal switching device according to claim 1 or 2, wherein in a case where the expansion board is detached from the switching unit, the switching unit outputs the signal from the base board.

5. The output signal switching device according to claim 1 or 2, wherein
the input signal of the switching unit is a video signal,
the expansion board is a video card, and
an output signal from the switching unit or the video card is outputted to a display.

6. The output signal switching device according to claim 1 or 2, wherein the switching unit is connected to a North Bridge.

7. The output signal switching device according to claim 1 or 2, further comprising an interface to connect the expansion board to the base board.

8. The output signal switching device according to claim 1 or 2, wherein the detection resistor is used also for detection of the expansion board by an interface of the base board.

9. The output signal switching device according to claim 1 or 2, wherein the switching unit includes a gate IC.
